(19) United States
(12) Patent Application Publication
(10) Pub. No.: US 2025/0268080 A1
(43) Pub. Date: Aug. 21, 2025

(54) DISPLAY DEVICE

(71) Applicant: Samsung Display Co., LTD., Yongin-si (KR)

(72) Inventors: Soo Hye RYU, Yongin-si (KR); Hong Jo PARK, Yongin-si (KR); Hye Min LEE, Yongin-si (KR); Baek Min OH, Yongin-si (KR); Eung Gyu LEE, Yongin-si (KR); Eun Je JANG, Yongin-si (KR)

(21) Appl. No.: 18/830,373

(22) Filed: Sep. 10, 2024

(30) Foreign Application Priority Data
Feb. 20, 2024 (KR) 10-2024-0024383

(51) Int. Cl. H10K 59/80; H10K 59/38

(52) U.S. Cl. CPC H10K 59/8792; H10K 59/38

(57) ABSTRACT

A display device includes: a substrate having a main region where a plurality of pixel electrodes spaced apart from each other are located, and a sub-region on one side of the main region and comprising a bending area; a plurality of color filters overlapping the pixel electrode on the substrate; a first color pattern on the substrate and partially overlapping the bending area in the sub-region; a first color dam spaced apart from the first color pattern and in the sub-region, and a second color dam spaced apart from the first color dam; and an overcoat layer on the color filter and in the main region and the sub-region, wherein the overcoat layer covers the main region and is on an inside of the second color dam in the sub-region.

### CROSS-REFERENCE TO RELATED APPLICATION

The present application claims priority to and the benefit of Korean Patent Application No. 10-2024-0024383, filed on Feb. 20, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

With the advance of information-oriented society, more and more demands are placed on display devices for displaying images in various ways. For example, display devices may be utilized in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, because each of pixels of a display panel includes a light emitting element capable of emitting light by itself, an image can be displayed without a backlight unit providing light to the display panel.

The above information disclosed in this Background section is only for enhancement of understanding of the background and therefore the information discussed in this Background section does not necessarily constitute prior art.

### SUMMARY

Aspects of some embodiments of the present disclosure include a display device including an overcoat layer formed through an inkjet printing process and dams formed from the same layer as a color filter.

Aspects of some embodiments of the present disclosure include a display device having a structure in which a manufacturing process is shortened.

However, aspects of embodiments according to the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, a display device includes: a substrate having a main region where a plurality of pixel electrodes spaced apart from each other are located, and a sub-region on one side of the main region and including a bending area, a plurality of color filters overlapping the pixel electrode on the substrate, a first color pattern on the substrate and partially overlapping the bending area in the sub-region, a first color dam spaced apart from the first color pattern and in the sub-region, and a second color dam spaced apart from the first color dam, and an overcoat layer on the color filter and in the main region and the sub-region, wherein the overcoat layer covers the main region and is on an inside of the second color dam in the sub-region.

According to some embodiments, each of the first color pattern, the first color dam, and the second color dam contains the same material as the color filter.

According to some embodiments, a part of the first color pattern is between the main region and the bending area of the sub-region, and the first color dam is spaced apart from the first color pattern outside the bending area.

According to some embodiments, the overcoat layer overlaps the first color pattern in the sub-region.

According to some embodiments, the display device may further comprise a bending protection layer on the overcoat layer and overlapping the bending area.

According to some embodiments, the display device may further comprise a bending structure comprising a plurality of via layers in the bending area and a wiring layer between the via layers, wherein at least a part of the first color pattern covers the bending structure.

According to some embodiments, the first color pattern completely covers the bending structure.

According to some embodiments, the overcoat layer fills a first valley portion formed between the first color dam and the first color pattern and is on an inside of the first color dam.

According to some embodiments, a part of the first color pattern is outside the bending area of the sub-region, the first color dam is between the bending area and the main region, and the second color dam is between the first color dam and the bending area.

According to some embodiments, the overcoat layer does not overlap the first color pattern.

According to some embodiments, the overcoat layer is on an inside of the first color dam.

According to some embodiments, each of the first color dam and the second color dam has a width in a range of 30 μm to 60 μm, and a valley portion formed between the first color dam and the second color dam has a width in a range of 30 μm to 60 μm.

According to some embodiments, the display device does not comprise a polarizing plate.

According to some embodiments, the display device may further comprise a light blocking layer in the main region and comprising a plurality of holes overlapping the plurality of pixel electrodes, wherein the plurality of color filters are respectively overlapping the holes of the light blocking layer.

According to some embodiments, the plurality of color filters overlap each other on the light blocking layer.

According to some embodiments, among the plurality of color filters, different color filters adjacent to each other overlap each other, the display device further comprising a plurality of color light blocking layers in a region where the different color filters overlap.

According to some embodiments of the present disclosure, a display device includes, a main region in which a plurality of pixel electrodes arranged in a first direction and a second direction are located, and a sub-region on one side of the main region in the first direction and in which a bending area is formed, a light blocking layer including a plurality of holes overlapping the plurality of pixel electrodes in the main region, a plurality of color filters on the light blocking layer and respectively correspond to the plurality of holes, a first color pattern in the sub-region, and at least partially overlapping the bending area, a first color dam in the sub-region and spaced apart from the first color pattern, and a second color dam spaced apart from the first color dam, and an overcoat layer covering a part of the sub-region and the main region, wherein each of the first color pattern, the first color dam, and the second color dam is on the same layer as one of the color filters, and the overcoat layer is on an inside of at least one of the first color dam or the second color dam in the sub-region.

According to some embodiments, a part of the first color pattern is between the main region and the bending area of the sub-region, and the first color dam is outside the bending area.

According to some embodiments, a part of the first color pattern is outside the bending area of the sub-region, the first color dam is between the bending area and the main region, and the second color dam is between the first color dam and the bending area.

According to some embodiments, the light blocking layer comprises at least one trench formed on an outer side of the hole and penetrating the light blocking layer.

In the display device according to some embodiments, the overcoat layer may be formed through an inkjet printing process, and the dams that prevent or reduce instances of the overcoat layer overflowing may be formed of the same material as the color filter. Accordingly, the display device may have a relatively shortened manufacturing process by reducing a mask process for forming the dams and the overcoat layer.

However, effects according to the embodiments of the present disclosure are not limited to those described above and various other effects are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a schematic perspective view of an electronic device according to some embodiments;

FIG. 2 is a perspective view illustrating a display device included in an electronic device according to some embodiments;

FIG. 3 is a cross-sectional view of the display device of FIG. 2 viewed from the side;

FIG. 4 is a plan view of the display device of FIG. 2;

FIG. 5 is a plan view illustrating the arrangement of holes of a light blocking layer and a pixel electrode in the display area of the display device according to some embodiments;

FIG. 6 is a plan view illustrating the arrangement of color filters and a pixel electrode in the display area of the display device according to some embodiments;

FIG. 7 is a cross-sectional view of a display device according to some embodiments;

FIG. 8 is a plan view illustrating the arrangement of the color filter layer in a cell unit of the display device according to some embodiments;

FIG. 9 is a cross-sectional view taken along the line X-X′ of FIG. 8;

FIG. 10 is a cross-sectional view showing a bending area of a display device according to some embodiments;

FIG. 11 is a plan view illustrating the arrangement of a color filter layer in a cell unit of a display device according to some embodiments;

FIG. 12 is a cross-sectional view taken along the line X1-X1′ of FIG. 11;

FIG. 13 is a plan view illustrating the arrangement of a color filter layer in a cell unit of a display device according to some embodiments;

FIG. 14 is a cross-sectional view taken along the line X2-X2′ of FIG. 13;

FIG. 15 is a plan view illustrating an opening in a light blocking layer of a display device according to some embodiments;

FIGS. 16 to 18 are cross-sectional views of a display device according to some embodiments; and

FIG. 19 is a plan view illustrating the arrangement of an opening of a pixel defining layer and color filters in a display area of a display device according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

Hereinafter, aspects of some embodiments will be described with reference to the accompanying drawings.

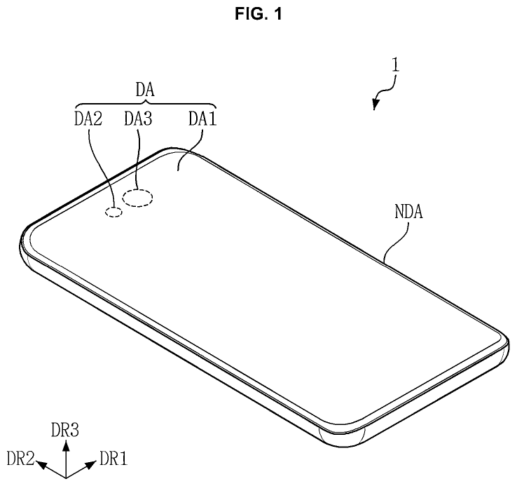

FIG. 1 is a schematic perspective view of an electronic device according to some embodiments.

Referring to FIG. 1, an electronic device 1 displays moving images (e.g., video images) or still images (e.g., static images). The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which include a display screen.

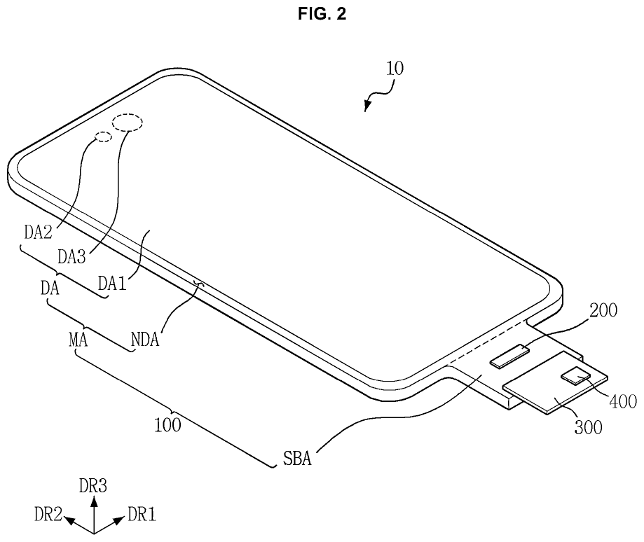

The electronic device 1 may include a display device 10 in FIG. 2 providing a display screen. Examples of the display device may include an inorganic light emitting diode display device, an organic light emitting display device, a quantum dot light emitting display device, a plasma display device and a field emission display device. In the following description, a case where an organic light emitting diode display device is applied as a display device will be illustrated, but embodiments according to the present disclosure are not limited thereto, and other display devices may be applied within the same scope of technical spirit.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes and a circular shape. The shape of a display area DA of the electronic device 1 may also be similar to the overall shape of the electronic device 1. FIG. 1 illustrates the electronic device 1 having a rectangular shape elongated in a second direction DR2.

The electronic device 1 may include the display area DA and a non-display area NDA. The display area DA is an area where images can be displayed, and the non-display area NDA is an area where images are not displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 are areas in which components for adding various functions to the electronic device 1 are located, and the second display area DA2 and the third display area DA3 may correspond to a component area.

FIG. 2 is a perspective view illustrating a display device included in an electronic device according to some embodiments.

Referring to FIG. 2, the electronic device 1 according to some embodiments may include the display device 10. The display device 10 may provide a screen displayed by the electronic device 1. The display device 10 may have a planar shape similar to the shape of the electronic device 1. For example, the display device 10 may have a shape similar to a rectangular shape having a short side in a first direction DR1 and a long side in the second direction DR2. The edge where the short side in the first direction DR1 and the long side in the second direction DR2 meet may be rounded to have a curvature, but is not limited thereto and may be formed at a right angle. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

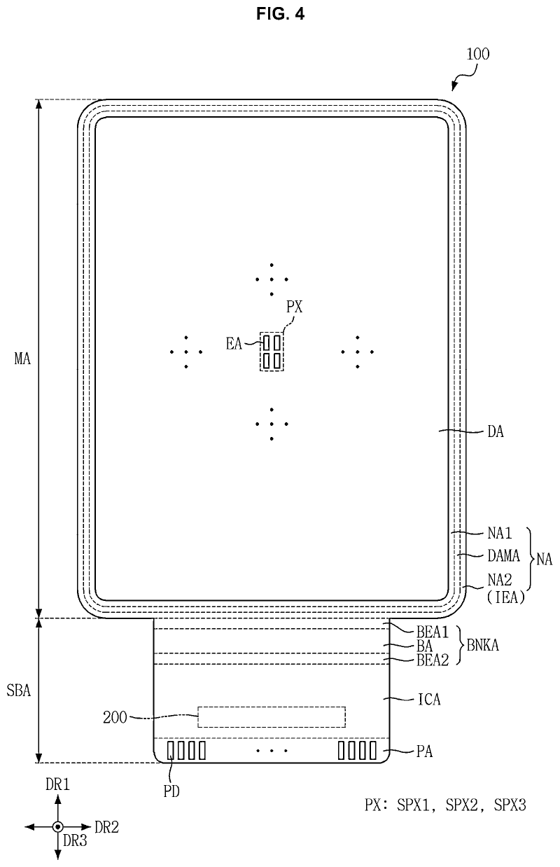

The main region MA may include the display area DA including pixels PX (see FIG. 4) displaying images and the non-display area NDA arranged around the display area DA. The display area DA may be located in the center of the main region MA, and the non-display area NDA may surround (e.g., in a periphery or outside a footprint of) the display area DA. The display area DA may include the first display area DA1, the second display area DA2, and the third display area DA3. The display area DA may emit light from a plurality of emission areas or a plurality of opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The non-display area NDA may be an area outside the display area DA. The non-display area NDA may be defined as an edge area of the main region MA of the display panel 100. The non-display area NDA may include a gate driver that supplies gate signals to the gate lines, and fan-out lines that connect the display driver 200 to the display area DA.

The sub-region SBA may be a region extending from one side of the main region MA. The sub-region SBA may include a flexible material which can be bent, folded or rolled. For example, when the sub-region SBA is bent, the sub-region SBA may overlap the main region MA in a thickness direction (third direction DR3). The sub-region SBA may include the display driver 200 and a pad portion connected to the circuit board 300. According to some embodiments, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be located in the sub-region SBA, and may overlap the main region MA in the thickness direction by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a frequency (e.g., a set or predetermined frequency). The touch driver 400 may calculate whether an input is made and input coordinates based on an amount of change in capacitance between the plurality of touch electrodes. The touch driver 400 may be formed as an integrated circuit (IC).

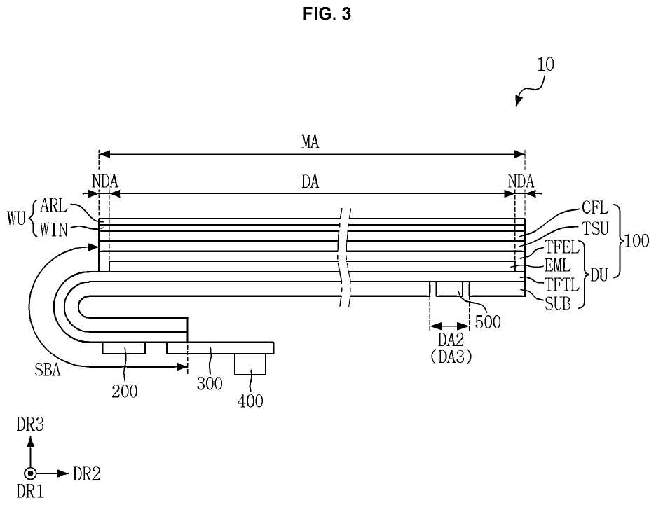

FIG. 3 is a cross-sectional view of the display device of FIG. 2 viewed from the side. FIG. 3 illustrates the sub-region SBA of the display panel 100 in the display device 10 of FIG. 2 in a folded state.

Referring to FIG. 3, the display panel 100 may include a display layer DU, a touch sensing layer TSU, a color filter layer CFL, and a cover window WU. The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but embodiments according to the present disclosure are not limited thereto. According to some embodiments, the substrate SUB may include a glass material or a metal material.

The thin film transistor layer TFTL may be located on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be located in the display area DA, the non-display area NDA, and the sub-region SBA. Thin film transistors, gate lines, data lines, and power lines of each of the pixels of the thin film transistor layer TFTL may be located in the display area DA. Gate control lines and fan-out lines of the thin film transistor layer TFTL may be located in the non-display area NDA. The lead lines of the thin film transistor layer TFTL may be located in the sub-region SBA.

The light emitting element layer EML may be located on the thin film transistor layer TFTL. The light emitting element layer EML may include a plurality of light emitting elements each including a first electrode, a second electrode, and a light emitting layer to emit light, and a pixel defining layer defining pixels. The plurality of light emitting elements of the light emitting element layer EML may be located in the display area DA.

According to some embodiments, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

According to some embodiments, the light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

The touch sensing layer TSU may be located on the encapsulation layer TFEL. The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

According to some embodiments, the touch sensing layer TSU may be located on a separate substrate located on the display layer DU. In this case, the substrate supporting the touch sensing layer TSU may be a base member that encapsulates the display layer DU.

The plurality of touch electrodes of the touch sensing layer TSU may be located in a touch sensor area overlapping the display area DA. The touch lines of the touch sensing layer TSU may be located in a touch peripheral area that overlaps the non-display area NDA.

The color filter layer CFL may be located on the touch sensing layer TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent or reduce color distortion caused by reflection of the external light. In some embodiments, the display device 10 may not form a polarizing plate on the front surface of the display panel 100, may form a pixel defining layer PDL of the display panel 100, which will be described later, with a black organic material, and may form the color filter layer CFL thereabove, so that it is possible to prevent or reduce instances of external light being reflected from an electrode or the like to be transmitted to the user although the external light enters the inside.

Because the color filter layer CFL is directly located on the touch sensing layer TSU, the display device 10 may not require a separate substrate for the color filter layer CFL. Accordingly, the thickness of the display device 10 may be relatively small.

In some embodiments, the display device 10 may further include an optical device 500. The optical device 500 may be located in the second display area DA2 or the third display area DA3. The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor.

The cover window WU may be located on the color filter layer CFL. The cover window WU may include a window WIN and an anti-reflection layer ARL.

The window WIN may be located on a light blocking member and a color filter layer 220/230, and may be attached to the light blocking member and the color filter layer CFL using a transparent adhesive. The window WIN may serve to protect the display panel 100. The window WIN may be made of a transparent material. The window WIN may be made of, for example, glass or plastic.

When the window WIN includes glass, the glass may be ultra-thin glass (UTG) or thin glass. The ultra-thin glass may be strengthened to have a predetermined stress profile therein. The strengthened ultra-thin glass more efficiently prevents or reduces generation of cracks, propagation of cracks, breakage and the like due to external impact than before strengthening. The ultra-thin glass strengthened by a strengthening process may have a different stress for each region.

When the glass is ultra-thin glass or thin glass, it may have a flexible property so that it can be curved, bent, folded, or rolled. The thickness of the glass may be, for example, in the range of 10 micrometers (μm) to 300 μm, particularly, 10 μm to 100 μm or about 50 μm. The glass of the window WIN may include soda-lime glass, alkali aluminosilicate glass, borosilicate glass, or lithium alumina silicate glass. The glass of the window WIN may include chemically strengthened or thermally strengthened glass to have strong rigidity. Chemical strengthening may be achieved through an ion exchange process in alkaline salts. The ion exchange process may be performed two or more times. In addition, the window WIN may be obtained by coating glass thin films on both surfaces of the polymer film.

An anti-reflection layer ARL may be positioned on the front of the window WIN, and the anti-reflection layer ARL may be attached to the front surface of the window WIN in the form of an optical film.

The anti-reflection layer ARL may be located on the window WIN. The anti-reflection layer ARL may protect the window WIN and reduce reflection of external light.

The anti-reflection layer ARL may include a hard coating layer and a low refractive layer, and may play a role in preventing or reducing reflection of external light by forming the layers such that external light is lost or destructive interference occurs at the boundary surface due to the two layers with different refractive indices. Here, the low refractive layer may have a configuration including particles dispersed in a transparent resin. Meanwhile, according to some embodiments, a high refractive layer may be further included, and the high refractive layer may be positioned between the hard coating layer and the low refractive layer.

The hard coating layer, the low refractive layer, and/or the high refractive layer that may be included in the anti-reflection layer ARL may have the following characteristics.

The hard coating layer may reduce warpage or lifting phenomena of the anti-reflection layer ARL under harsh conditions such as high temperature and high humidity and thus may improve reliability problems.

The hard coating layer may include an organic layer. The organic layer may include at least one of an acrylate-based compound, a urethane-based compound, polyimide, polycarbonate, polyethersulfone, polyethylene naphthalate, polyphenylene sulfide, liquid crystal polymer (LCP), polymethyl methacrylate, or epoxy-based polymer, or a combination thereof.

According to some embodiments, the hard coating layer may include an organic layer and an organic-inorganic composite layer. In this case, the organic layer may include an acrylate-based compound. For example, the organic layer may be formed to include urethane acrylate. The organic layer may serve as a stress buffer layer.

The organic material in the organic-inorganic composite layer may be formed from at least one of an acrylate-based compound, a polyurethane-based compound, or an epoxy-based compound, or a combination thereof. For example, the organic material may include urethane acrylate. The inorganic material in the organic-inorganic composite layer may be at least one selected from the group consisting of silicon oxide (SiO₂), zirconium oxide (ZrO₂), aluminum oxide (Al₂O₃), tantalum oxide (Ta₂O₅), niobium oxide (Nb₂O₅ or NbO₂), and glass beads.

The inorganic material may be provided in the form of a single type of inorganic oxide listed above or a mixture thereof. Additionally, the inorganic material may be provided in various forms to form an organic-inorganic composite layer. For example, silicon oxide may be provided in the form of particles, sol, or having a hollow shape.

In the organic-inorganic composite layer, the acrylate compound that is an organic material and inorganic particles may be provided by being mixed at a weight ratio of 5:5 to 8:2. By including both an acrylate compound and inorganic particles, the organic-inorganic composite layer may improve surface hardness and have impact absorbency against external impact, and thus may form a hard coating layer that is not easily broken.

According to some embodiments, the hard coating layer may include an acrylate-based compound and a urethane-based compound. The acrylate-based compound and the urethane-based compound may be mixed and polymerized in a monomer form. The acrylate-based compound may increase the hardness and wear resistance of the anti-reflection layer ARL by increasing the hardness of the low refractive layer. The urethane-based compound may increase the elasticity of the anti-reflection layer ARL by providing flexibility to the low refractive layer. In this case, the ratio of the acrylate-based compound in the hard coating layer may be 70% to 99.9%, and the ratio of the urethane-based compound may be 0.1 to 30%. For example, the mixing ratio of the acrylate-based compound and the urethane-based compound may be 7:3 or more, and the ratio of the acrylate-based compound may be further increased. For example, in the mixing ratio of the acrylate-based compound and the urethane-based compound, the ratio of the acrylate-based compound may be further increased, such as 7:3, 8:2, or 9:1.

According to some embodiments, the hard coating layer may include an acrylate-based compound. In this case, the acrylate-based compound may be an acrylic resin. That is, the hard coating layer may improve the hardness and wear resistance of the anti-reflection layer ARL by including acrylic resin.

The thickness of the hard coating layer may be 2 μm to 10 μm. The hard coating layer may be configured in the above thickness range, and thus may reduce warpage or lifting phenomena, so that reliability problems may be improved.

The refractive index of the hard coating layer may be 1.48 to 1.53. The hard coating layer may be configured in the above refractive index range and thus have a difference in refractive indices at the interface with the low refractive layer, which will be described in more detail later, and may refract the light emitted from the light emitting element layer upward to increase light emission efficiency and reduce reflection of external light.

The low refractive layer may be located on the hard coating layer. The low refractive layer may refract the light emitted from the light emitting element layer upward to increase light emission efficiency and reduce reflection of external light.

The low refractive layer may include particles dispersed in a transparent resin.

The resin may include one or more selected from the group consisting of acrylic, polysiloxane, polyurethane, polyurethane acrylate, polyimide, polymethylsilsesquioxane (PMSSQ), and polymethyl methacrylate (PMMA).

The particles may be hollow particles. For example, the particles may include one or more selected from the group consisting of silica (SiO₂), magnesium fluoride (MgF₂), and iron oxide (Fe₃O₄). Further, the particle may include a shell made of one or more of the above materials and a hollow in the shell. According to some embodiments, the particle may have a diameter of 10 to 200 nm, and the diameter of the particle may determine the thickness of the shell and the diameter of the hollow.

The particles may be contained in the low refractive layer in a weight ratio of 10% to 50% to the resin. When the weight ratio of the particles to the resin is 10% or more, the refractive index of the low refractive layer may be reduced. When the weight ratio of the particles to the resin is 50% or less, deterioration of adhesion to the adjacent layers may be prevented or reduced. The low refractive layer may be formed by coating and curing a solution containing a solvent in which the resin and the particles are dispersed.

The thickness of the low refractive layer may be 10 to 200 nm. The low refractive layer may be configured in the above thickness range, and thus may include sufficient particles to lower the refractive index and improve adhesive strength to the lower layer.

The refractive index of the low refractive layer may be smaller than the refractive index of the hard coating layer. For example, the refractive index of the low refractive layer may be at least 0.05 smaller than the refractive index of the hard coating layer. When the difference between the refractive indices of the low refractive layer and the hard coating layer is 0.05 or more, total reflection of external light may be increased at the interface between the low refractive layer and the hard coating layer, which may induce destructive interference with light reflected from the surface of the low refractive layer. Accordingly, the reflectivity of external light of the anti-reflection layer ARL may be reduced. The refractive index of the low refractive layer may be in the range of 1.3 to 1.43. However, embodiments according to the present disclosure are not limited thereto, and a lower refractive index may be used within a range smaller than the refractive index of the hard coating layer.

Meanwhile, the high refractive layer may include an inorganic material, an organic material, or an inorganic material and an organic material. Accordingly, the high refractive layer may be formed of an inorganic layer, an organic layer, or an organic layer containing inorganic particles.

The inorganic material contained in the high refractive layer may be one or more selected from the group consisting of zinc oxide, titanium oxide, zirconium oxide, niobium oxide, tantalum oxide, tin oxide, nickel oxide, silicon oxide, silicon nitride, indium nitride, and gallium nitride.

The organic material contained in the high refractive layer may be one or more selected from the group consisting of poly(3,4-ethylenedioxythiophene) (PEDOT), 4,4′-bis[N-(3-methylphenyl)-N-phenyl amino]biphenyl (TPD), 4,4′,4″-tris [(3-methylphenyl)phenyl amino]triphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′-bis[N,N-bis(3-methylphenyl)-Amino]-diphenylmethane (BPPM), 4,4′-dicarbazolyl-1,1′-biphenyl (CBP), 4,4′,4″-tris(N-carbazole)triphenylamine (TCTA), 2,2′,2″-(1,3,5-benzenetolyl)tris-[1-phenyl-1H-benzoimidazole] (TPBI), and 3-(4-biphenyl)-4-phenyl-5-t-butylphenyl-1,2,4-triazole (TAZ).

The refractive index of the high refractive layer may be greater than the refractive index of the low refractive layer to reduce reflection of external light. For example, the refractive index of the high refractive layer may be at least 0.05 greater than the refractive index of the low refractive layer. The refractive index of the high refractive layer may range from 1.53 to 1.7. However, embodiments according to the present disclosure are not limited thereto, and a larger refractive index may be used within a range larger than the refractive index of the low refractive layer.

The thickness of the high refractive layer may be 50 to 200 nanometers (nm). The high refractive layer may be configured within the above thickness range, and thus may form the interface that is flat with the low refractive layer and prevent or reduce instances of the bonding strength with the hard coating layer decreasing.

The anti-reflection layer ARL further including a high refractive layer may further reduce reflection of external light by increasing the difference in refractive indices at the interface with the low refractive layer.

According to some embodiments, another optical film other than the anti-reflection layer ARL may be further included on the front surface of the window WIN, and an anti-fingerprint layer may be included. However, a polarizing plate may not be included, and this is because the light blocking member and the color filter layer CFL, which will be described later, may lower the reflectivity of external light and make it less visible to the user. Accordingly, according to some embodiments, the anti-reflection layer ARL may not be included on the front surface of the window WIN.

FIG. 4 is a plan view of the display device of FIG. 2. FIG. 4 shows the display device 10 in an unbent and unfolded state.

Referring to FIG. 4, the display device 10 may include the main region MA and the sub-region SBA. The main region MA may include the display area DA and the non-display area NA, and the sub-region SBA may include a bank area BNKA, a driving circuit mounting area ICA, and a pad area PA.

The display area DA may be an area where a plurality of pixels PX are located. The pixels PX and wires (or some of the wires) connected to the pixels PX may be located in the display area DA.

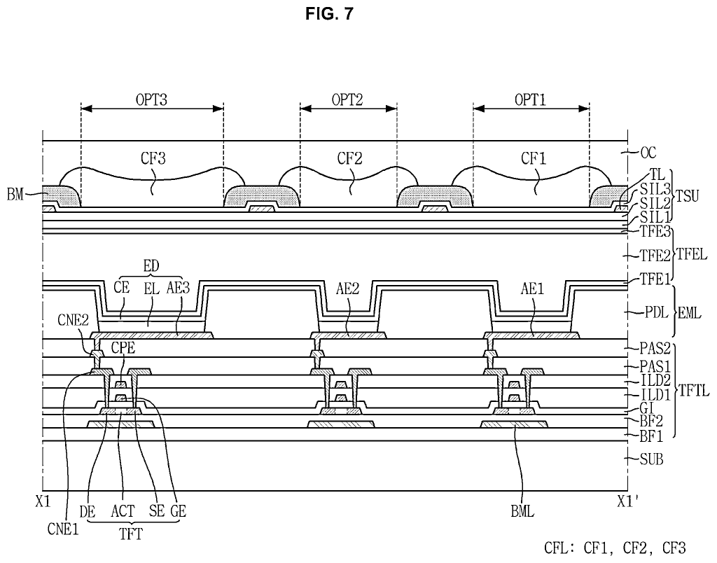

The pixels PX may be provided in the thin film transistor layer TFTL and the light emitting element layer EML of the display device 10. As an example, each of the pixels PX may include a pixel circuit including circuit elements located on the thin film transistor layer TFTL and a light emitting element (e.g., a light emitting element ED in FIG. 7) located on the light emitting element layer EML.

The pixels PX may include at least two color emission areas EA that emit light of different colors. For example, the pixels PX may include a first color emission area emitting light of a first color (e.g., red light), a second color emission area emitting light of a second color (e.g., green light), and a third color emission area emitting light of a third color (e.g., blue light).

At least one first color emission area, at least one second color emission area, and at least one third color emission area adjacent to each other may constitute one unit pixel PX. For example, one first color emission area, two second color emission areas, and one third color emission area adjacent to each other may constitute one unit pixel PX. Each unit pixel PX may emit light of various colors, including white light, by color mixing of light emitted from the emission areas constituting the unit pixel PX. According to some embodiments, the first color emission area and the third color emission area may be arranged alternately in the first direction DR1 and/or the second direction DR2, and the second color emission areas may be arranged continuously and/or sequentially in the first direction DR1. The type, shape, and/or arrangement structure of the emission areas may be changed depending on the embodiments. Additionally, the type, number, ratio, and/or arrangement structure of the emission areas constituting each of the unit pixels PX may also be changed depending on the embodiments.

The encapsulation layer TFEL may be located on the pixels PX. For example, the encapsulation layer TFEL may be provided in at least the display area DA to cover the pixels PX, and a part of the encapsulation layer TFEL may extend into the non-display area NA.

A plurality of wires may be provided in the thin film transistor layer TFTL and may be positioned in the display area DA and the non-display area NA. In addition, wires may be positioned also in the sub-region SBA. For example, the wires may extend from the sub-region SBA through the non-display area NA to the display area DA.

The non-display area NA may be located around the display area DA. For example, the non-display area NA may be an edge area of the main region MA positioned outside the display area DA.

The non-display area NA may include a dam area DAMA spaced apart from the display area DA, a first non-display area NA1 between the display area DA and the dam area DAMA, and a second non-display area NA2 outside the dam area DAMA. The dam area DAMA may be an area in which a dam surrounding the display area DA is located. The second non-display area NA2 may include an inorganic encapsulation area IEA (also referred to as a “bonding area”) in which the inorganic encapsulation layers of the encapsulation layer TFEL are bonded to each other.

The sub-region SBA may include the bank area BNKA, the driving circuit mounting area ICA, and the pad area PA sequentially arranged on one side of the main region MA. Wires (or parts of wires), banks, and the pads PD may be located in the sub-region SBA. At least some of the wires may extend into the main region MA and be connected to the pixels PX.

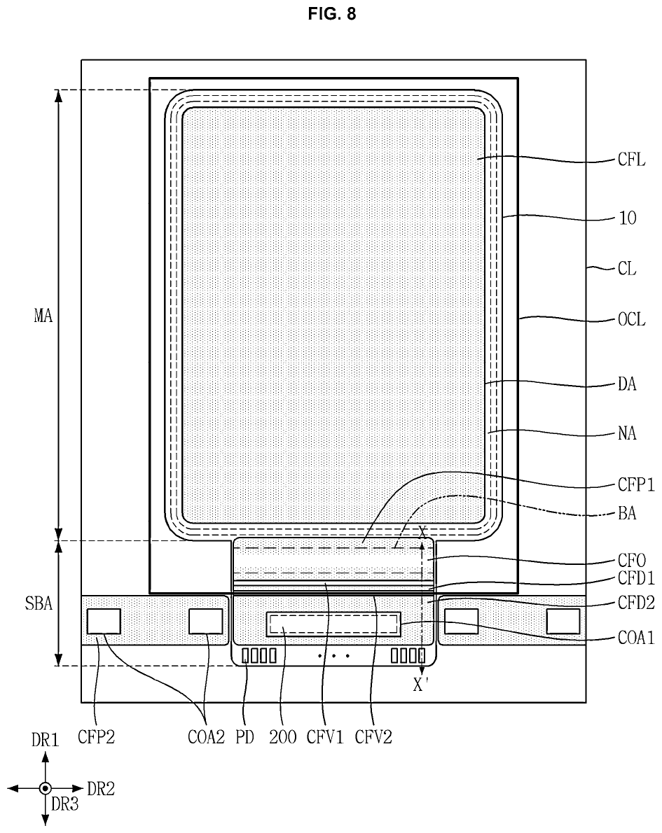

The bank area BNKA may be an area in which at least one bank is located. According to some embodiments, the bank area BNKA may overlap a bending area BA. For example, the bank area BNKA may include the bending area BA spaced apart from the main region MA, and a first edge area BEA1 and a second edge area BEA2 positioned on both sides of the bending area BA in the first direction DR1. The bank may be provided in the bending area BA and the peripheral areas thereof (e.g., the first edge area BEA1 and the second edge area BEA2 of the bank area BNKA) to cover wires passing through the bending area BA. The display panel 100 may be bent in the bending area BA such that a part of the sub-region SBA may be positioned behind the main region MA. The display device 10 according to some embodiments may include a color pattern CFP1 (see FIG. 8) that is located in the bank area BNKA and includes the same material as the color filter of the color filter layer CFL. In the display device 10, the color pattern CFP1, which is located in the bank area BNKA and prevents or reduces instances of an overcoat layer OC (see FIG. 7) described later overflowing, may be located on the same layer as the color filter. The display device 10 may form the color pattern CFP1 that serves as a bank in the process of forming a color filter, and the manufacturing process may be shortened. A more detailed description of the color pattern CFP1 located in the sub-region SBA will be described in more detail later.

The driving circuit mounting area ICA may be an area in which the driver 200 is located. Pads for connecting at least some of the wires to the driver 200 may be located in the driving circuit mounting area ICA. For example, in the driving circuit mounting area ICA, input pads for connecting the driver 200 to the specific pads (e.g., data input pads) of the pad area PA and output pads for connecting the driver 200 to the pixels PX may be located.

According to some embodiments, the driver 200 may not be located on the display device 10. In this case, the display device 10 may not include the driving circuit mounting area ICA, and only wires may be located in an area between the bank area BNKA and the pad area PA.

The pad area PA may be an area where the pads PD for connecting the display device 10 and/or the driver 200 to the circuit board 300 and the like are located. The circuit board 300 may be arranged or bonded on the pad area PA.

A plurality of pads PD including power pads and signal pads connected to the pixels PX, the driver 200, and/or the embedded circuit may be located in the pad area PA. Power voltages for driving the pixels PX, the driver 200, and/or the embedded circuit or the like may be supplied to the power pads. Driving signals and/or image data for driving the pixels PX, the driver 200, and/or the embedded circuit or the like may be supplied to the signal pads. The type, location, arrangement order, and/or number of the pads PD may be variously changed according to embodiments.

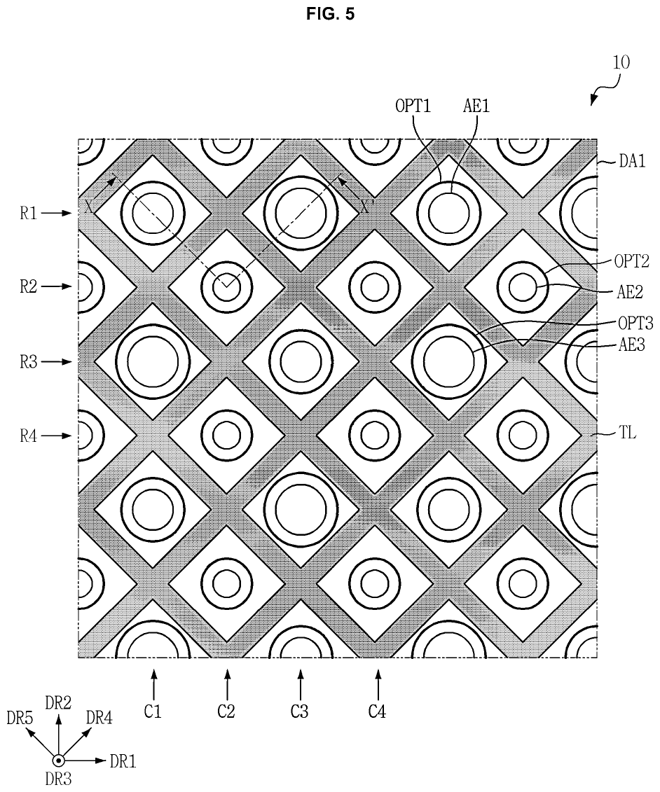

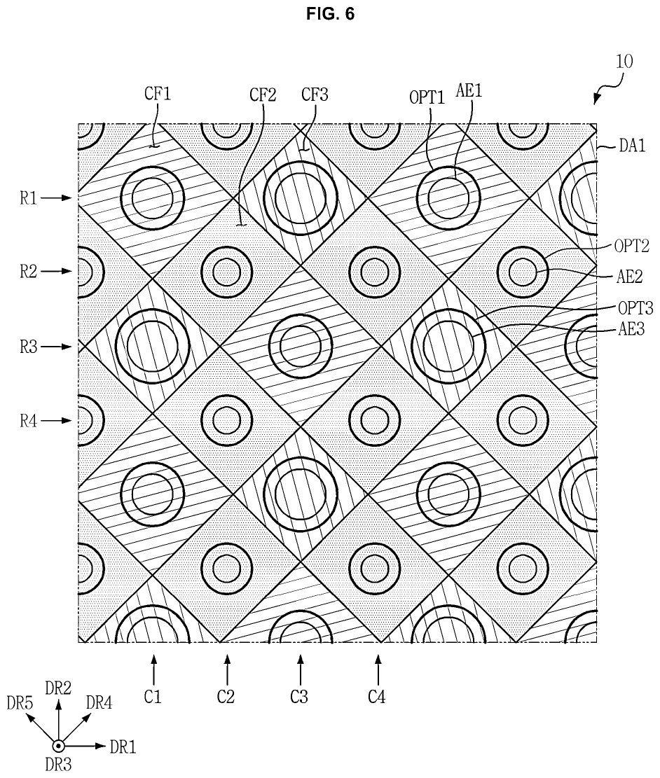

FIG. 5 is a plan view illustrating the arrangement of holes of a light blocking layer and a pixel electrode in the display area of the display device according to some embodiments. FIG. 6 is a plan view illustrating the arrangement of color filters and a pixel electrode in the display area of the display device according to some embodiments. FIGS. 5 and 6 illustrate the arrangement of pixel electrodes AE1, AE2, and AE3 and holes OPT1, OPT2, and OPT3 in a light blocking layer BM located in the first display area DA1.

Referring to FIGS. 5 and 6, the display device 10 may include a plurality of pixel electrodes AE1, AE2, and AE3 located in the display area DA. The plurality of emission areas EA1, EA2, and EA3 may be arranged in a PenTile™ type, e.g., a diamond PenTile™ type. For example, the plurality of pixel electrodes AE1, AE2, and AE3 may be arranged in a fourth direction DR4 and a fifth direction DR5, which are diagonal directions between the first direction DR1 and the second direction DR2. The first pixel electrode AE1 and the second pixel electrode AE2 may be located adjacent to each other in the fifth direction DR5, and the second pixel electrode AE2 and the third pixel electrode AE3 may be located adjacent to each other in the fourth direction DR4. The first pixel electrode AE1 and the third pixel electrode AE3 may be arranged to be spaced apart from each other in the second direction DR2. In the arrangement of the pixel electrodes AE1, AE2, and AE3, in a first row R1 and a third row R3, the first pixel electrode AE1 and the third pixel electrode AE3 may be alternately arranged in the first direction DR1. In a first column C1 and a third column C3, the first pixel electrode AE1 and the third pixel electrode AE3 may be alternately arranged in the second direction DR2. In a second row R2 and a fourth row R4, the second pixel electrodes AE2 may be repeatedly arranged in the first direction DR1, and in a second row C2 and a fourth column C4, the second pixel electrodes AE2 may be repeatedly arranged in the second direction DR2.

The plurality of pixel electrodes AE1, AE2, and AE3 may be repeatedly arranged in the arrangement of FIG. 4 across the entirety of the display area DA. One pixel PX may include one first pixel electrode AE1, two second pixel electrodes AE2, and one third pixel electrode AE3. However, embodiments according to the present disclosure are not limited thereto. The number of the pixel electrodes AE1, AE2, and AE3 located in the pixel PX may vary.

Each of the pixel electrodes AE1, AE2, and AE3 may be an anode electrode of the light emitting element included in the pixel PX. One pixel PX may include one or more light emitting elements ED (see FIG. 8), and the light emitting elements may be light emitting elements that emit light of different colors. For example, a light emitting element including the first pixel electrode AE1 may emit first light of a red color. A light emitting element including the second pixel electrode AE2 may emit second light of a green color, and a light emitting element including the third pixel electrode AE3 may emit third light of a blue color. However, embodiments according to the present disclosure are not limited thereto. One first pixel electrode AE1, two second pixel electrodes AE2, and one third pixel electrode AE3 may form one pixel PX, and may emit different colors and express a white grayscale. However, embodiments according to the present disclosure are not limited thereto, and the combination of the pixel electrodes AE1, AE2, and AE3 constituting one pixel PX may be modified in various ways depending on the arrangement of the pixel electrodes AE1, AE2, and AE3, the color of light that the pixel electrodes AE1, AE2, and AE3 emit, and the like.

Each of the pixel electrodes AE1, AE2, and AE3 may form an emission area in each pixel PX. For example, the first pixel electrode AE1 may form a first emission area that emits light of the first color, the second pixel electrode AE2 may form a second emission area that emits light of the second color, and the third pixel electrode AE3 may form a third emission area that emits light of the third color. According to some embodiments, the emission area of the display device 10 may be an area overlapping the pixel electrodes AE1, AE2, and AE3, and for example, an opening of the pixel defining layer PDL (see FIG. 7) illustrated in FIG. 7 may correspond to the emission area. For example, each of the emission areas may be defined by a plurality of openings formed in the pixel defining layer PDL (see FIG. 7) of the light emitting element layer EML, which will be described in more detail later. The first emission area may be defined by a first opening overlapping the first pixel electrode AE1 in the pixel defining layer, the second emission area may be defined by a second opening overlapping the second pixel electrode AE2 in the pixel defining layer, and the third emission area may be defined by a third opening overlapping the third pixel electrode AE3 in the pixel defining layer.

According to some embodiments, the areas or sizes of the first to third pixel electrodes AE1, AE2, and AE3 may be different from each other. In the embodiments of FIG. 5, the area of the third pixel electrode AE3 may be larger than those of the first pixel electrode AE1 and the second pixel electrode AE2, and the area of the first pixel electrode AE1 may be larger than that of the second pixel electrode AE2. The intensity of light to be emitted may vary depending on the area of the emission area overlapping the pixel electrodes AE1, AE2, and AE3, and the area of the emission area may be adjusted to control the color of the screen displayed on the display device 10 or the electronic device 1. In the embodiments of FIG. 5, the third pixel electrode AE3 has the largest area, but is not limited thereto. The size of the pixel electrodes AE1, AE2, and AE3 and the area of the emission area may be freely adjusted according to the color of the screen required for the display device 10 and the electronic device 1. In addition, the areas of the pixel electrodes AE1, AE2, and AE3 may be related to light efficiency and the lifespan of the light emitting element ED, and may have a trade-off relation with the reflection by external light. The areas of the pixel electrodes AE1, AE2, and AE3 may be adjusted in consideration of the above factors.

The display device 10 may include the light blocking layer BM and a plurality of color filters CF1, CF2, and CF3 located on the pixel electrodes AE1, AE2, and AE3.

The light blocking layer BM may be arranged over the entire display area DA. The light blocking layer BM may include a plurality of holes OPT1, OPT2, and OPT3 arranged to respectively correspond to the plurality of pixel electrodes AE1, AE2, and AE3. Each of the holes OPT1, OPT2, and OPT3 of the light blocking layer BM may be arranged to correspond to the opening of the pixel defining layer PDL (see FIG. 7). The light blocking layer BM may cover the display area DA except for an area where the holes OPT1, OPT2, and OPT3 are located in the display area DA. The holes of the light blocking layer BM may be regions where lights emitted from the light emitting elements including the pixel electrodes AE1, AE2, and AE3 are emitted.

The plurality of holes OPT1, OPT2, and OPT3 may include a first hole OPT1 overlapping the first pixel electrode AE1, a second hole OPT2 overlapping the second pixel electrode AE2, and a third hole OPT3 overlapping the third pixel electrode AE3. One first hole OPT1, two second holes OPT2, and one third hole OPT3 may be formed in the light blocking layer BM within the area occupied by one pixel PX.

Each of the plurality of holes may have a larger area in a plan view than each of the pixel electrodes AE1, AE2, and AE3. For example, the first hole OPT1 may have a larger area in a plan view than the first pixel electrode AE1. The second hole OPT2 and the third hole OPT3 may also have larger areas in a plan view than the second pixel electrode AE2 and the third pixel electrode AE3, respectively. Further, each of the holes OPT1, OPT2, and OPT3 of the light blocking layer BM may have a different area in a plan view. As described above, the areas of the plurality of pixel electrodes AE1, AE2, and AE3 may be different from each other, and accordingly, the sizes of the holes OPT1, OPT2, and OPT3 in the light blocking layer BM may also be different from each other. For example, the diameter or size of the third hole OPT3 may be larger than those of the first hole OPT1 and the second hole OPT2, and the diameter or size of the first hole OPT1 may be larger than that of the second hole OPT2. However, embodiments according to the present disclosure are not limited thereto.

The plurality of color filters CF1, CF2, and CF3 may be arranged to respectively correspond to the pixel electrodes AE1, AE2, and AE3. For example, the color filters CF1, CF2, and CF3 may be located on the light blocking layer BM and may be arranged to correspond to the plurality of holes of the light blocking layer BM. The hole of the light blocking layer BM may be formed to overlap the opening of the pixel defining layer PDL (see FIG. 7), and may form a light exit area through which light emitted from the emission area is emitted. The color filters CF1, CF2, and CF3 may have areas larger than those of the holes of the light blocking layer BM, and the color filters CF1, CF2, and CF3 may completely cover the light exit area formed by the holes. Each of the color filters CF1, CF2, and CF3 may completely cover the holes of the light blocking layer BM, and a part thereof may be directly located on the light blocking layer BM. However, in some embodiments, the color filters CF1, CF2, and CF3 may be omitted.

The color filters CF1, CF2, and CF3 may include the first color filter CF1, the second color filter CF2, and the third color filter CF3 arranged to correspond to the different pixel electrodes AE1, AE2, and AE3, respectively. The color filters CF1, CF2, and CF3 may include a colorant such as a dye or pigment that absorbs light in a wavelength band different from light in a specific wavelength band, and may be arranged to correspond to the color of light emitted by a light emitting element including the pixel electrodes AE1, AE2, and AE3. For example, the first color filter CF1 may be a red color filter that is arranged to overlap the first pixel electrode AE1 and transmits only the first light of the red color. The second color filter CF2 may be a green color filter that is arranged to overlap the second pixel electrode AE2 and transmits only the second light of the green color, and the third color filter CF3 may be a blue color filter that is arranged to overlap the third pixel electrode AE3 and transmits only the third light of the blue color.

Similarly to the arrangement of the pixel electrodes AE1, AE2, and AE3, the color filters CF1, CF2, and CF3 may be arranged in a PenTile™ type of arrangement, e.g., a diamond PenTile™ type of arrangement. For example, the first color filter CF1 and the third color filter CF3 may be alternately arranged in the first direction DR1 and the second direction DR2. The second color filter CF2 and another adjacent second color filter CF2 may be arranged in the first direction DR1 and the second direction DR2, and the second color filter CF2 and the adjacent first color filter CF1 and the adjacent third color filter CF3 may be arranged in the fourth direction DR4 or the fifth direction DR5. The plurality of second color filters CF2 may be repeatedly arranged along the first direction DR1 and the second direction DR2, and the second color filter CF2 and the first color filter CF1, or the second color filter CF2 and the third color filter CF3 may be alternately arranged along the fourth direction DR4 or the fifth direction DR5.

According to some embodiments, the plurality of color filters CF1, CF2, and CF3 may have different areas in a plan view. As described above, the areas of the plurality of pixel electrodes AE1, AE2, and AE3 may be different from each other, and accordingly, the sizes of the holes of the light blocking layer BM, and the areas of the color filters CF1, CF2, and CF3 in a plan view may also be different from each other. For example, the area of the first color filter CF1, which is a red color filter, may be larger than the areas of the second color filter CF2, which is a green color filter, and the third color filter CF3, which is a blue color filter. Additionally, the area of the third color filter CF3 may be larger than the area of the second color filter CF2.

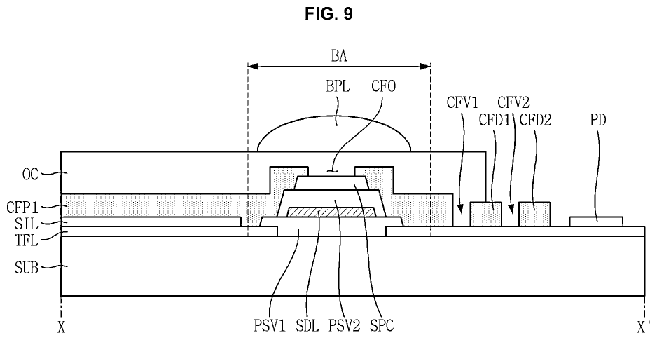

The color filters CF1, CF2, and CF3 may have a quadrilateral shape, a rectangular shape, or a rhombic shape including sides extending in the fourth direction DR4 and the fifth direction DR5. The first color filter CF1 and the third color filter CF3 may have sides of the same length extending in the fourth direction DR4 and the fifth direction DR5, and may have a quadrilateral shape or a rhombic shape in a plan view. The area of the first color filter CF1 in a plan view may be larger than the area of the third color filter CF3, and the second color filter CF2 adjacent to the first color filter CF1 and the third color filter CF3 may have sides of different lengths extending in the fourth direction DR4 and the fifth direction DR5 and have a rectangular shape in a plan view. In other words, the extending sides of the first color filter CF1 and the third color filter CF3 have the same length and thus may have shapes that are not affected by locations, whereas the extending sides of the second color filter CF2 have different lengths and thus may have different extension directions of the long sides depending on locations. In the case of describing the shape of the second color filters CF2 shown in FIG. 9, for example, the second color filter CF2 located in a second column C2 of a second row R2 may have a shape in which the long side extends in the fourth direction DR4, and the second color filter CF2 located in a fourth column C4 of the second row R2 and may have a shape in which the long side extends in the fifth direction DR5.

However, embodiments according to the present disclosure are not limited thereto. In some embodiments, the shape of the color filters CF1, CF2, and CF3 in a plan view may be a circular shape similar to the shape of the pixel electrodes AE1, AE2, and AE3. The display device 10 according to some embodiments may be designed such that the planar shape and area of the color filters CF1, CF2, and CF3 allow external light of the display device 10 to have a specific color.

According to some embodiments, the planar area ratio of the first color filter CF1 and the second color filter CF2 may be in a range of about 1:0.3 to 1:0.7, and the area ratio of the first color filter CF1 and the third color filter CF3 may be in a range of about 1:0.4 to 1:1. For example, the area ratio of the first color filter CF1, the second color filter CF2, and the third color filter CF3 may be 1:0.59:0.52 or 1:0.59:1. However, the area ratio of the color filters CF1, CF2, and CF3 is not limited to the above-described area ratio, and the planar areas of the color filters CF1, CF2, and CF3 may be designed differently such that the reflected light in the display device 10 and the electronic device 1 has desired color coordinates.

The display device 10 may include the color filters CF1, CF2, and CF3 located on the display layer DU to reduce the intensity of reflected light caused by external light. Furthermore, the color of the reflected light by the external light may be controlled by adjusting the arrangement, shape, and area of the color filters CF1, CF2, and CF3 in a plan view.

A touch electrode TL may be located between the pixel electrodes AE1, AE2, and AE3. The touch electrode TL may be arranged to extend in the fourth direction DR4 and the fifth direction DR5, and may be spaced apart from the pixel electrodes AE1, AE2, and AE3. The touch electrode TL may be arranged to overlap the pixel defining layer PDL (see FIG. 7) and the light blocking layer BM. Although the touch electrode TL is briefly illustrated in the drawing, the touch electrode TL may include a touch driving electrode and a sensing electrode.

FIG. 7 is a cross-sectional view of a display device according to some embodiments. FIG. 7 illustrates a cross section across the first to third pixel electrodes AE1, AE2, and AE3 in one pixel PX.

A cross-sectional structure of the display device 10 will be described with reference to FIG. 7. The display device 10 may include the display layer DU, the touch sensing layer TSU, the light blocking layer BM, the color filter layer CFL, and the overcoat layer OC. The display layer DU may include the substrate SUB, the thin film transistor layer TFTL, the light emitting element layer EML, and the encapsulation layer TFEL. The light blocking layer BM may be located on the touch sensing layer TSU of the display panel 100, and the color filters CF1, CF2, and CF3 of the color filter layer CFL may be located on the light blocking layer BM. The overcoat layer OC may be located on the color filter layer CFL and the light blocking layer BM.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be located on the substrate SUB. The first buffer layer BF1 may include an inorganic layer capable of preventing or reducing penetration of air or moisture. For example, the first buffer layer BF1 may include a plurality of inorganic layers alternately stacked.

The lower metal layer BML may be located on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. The second buffer layer BF2 may include an inorganic layer capable of preventing or reducing penetration of contaminants such as air or moisture. For example, the second buffer layer BF2 may include a plurality of inorganic layers alternately stacked.

The thin film transistor TFT may be located on the second buffer layer BF2, and may constitute a pixel circuit of each of a plurality of pixels. For example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be located on the second buffer layer BF2. The semiconductor layer ACT may overlap the lower metal layer BML and the gate electrode GE in the thickness direction, and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be located on the gate insulating layer Gl. The gate electrode GE may overlap the semiconductor layer ACT with the gate insulating layer GI interposed therebetween.

The gate insulating layer GI may be located on the semiconductor layer ACT. For example, the gate insulating layer GI may cover the semiconductor layer ACT and the second buffer layer BF2 to insulate the gate electrode GE from the semiconductor layer ACT. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be located on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be located on the second interlayer insulating layer ILD2. The first connection electrode CNE1 may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be located on the first passivation layer PAS1. The second connection electrode CNE2 may electrically connect the first connection electrode CNE1 to a pixel electrode AE of the light emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light emitting element layer EML may be located on the thin film transistor layer TFTL. The light emitting element layer EML may include the light emitting element ED and the pixel defining layer PDL. The light emitting element ED may include the pixel electrodes AE1, AE2, and AE3, a light emitting layer EL, and a common electrode CE.

The pixel electrodes AE1, AE2, and AE3 may be located on the second passivation layer PAS2. Each of the different pixel electrodes AE1, AE2, and AE3 may be arranged to overlap one of the different openings of the pixel defining layer PDL. The pixel electrodes AE1, AE2, and AE3 may be electrically connected to the drain electrode DE of the thin film transistor TFT through the first and second connection electrodes CNE1 and CNE2.

The light emitting layer EL may be located on the pixel electrodes AE1, AE2, and AE3. For example, the light emitting layer EL may be an organic light emitting layer made of an organic material, but is not limited thereto. In the case of employing the organic light emitting layer as the light emitting layer EL, the thin film transistor TFT applies a predetermined voltage to the pixel electrodes AE1, AE2, and AE3 of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

According to some embodiments, the light emitting layers EL located on different pixel electrodes AE1, AE2, and AE3 may emit light of different colors. For example, the light emitting layer located on the first pixel electrode AE1 may emit red light of the first color, the light emitting layer located on the second pixel electrode AE2 may emit green light of the second color, and the light emitting layer located on the third pixel electrode AE3 may emit blue light of the third color. However, embodiments according to the present disclosure are not limited thereto. According to some embodiments, the light emitting layer EL may be located as one common layer on the different pixel electrodes AE1, AE2, and AE3 and the pixel defining layer PDL, or the light emitting layer EL located on the different pixel electrodes AE1, AE2, and AE3 may emit light of the same color. In this case, the display device 10 may further include a color adjustment layer located on the light emitting elements ED.

The common electrode CE may be arranged on the light emitting layer EL. For example, the common electrode CE may be made in the form of an electrode common to all of the pixels rather than specific to each of the pixels. The common electrode CE may be located on the light emitting layer EL in the first to third pixel electrodes AE1, AE2, and AE3, and may be located on the pixel defining layer PDL in an area other than the first to third pixel electrodes AE1, AE2, and AE3.

The common electrode CE may receive the common voltage or a low potential voltage. When the pixel electrode AE receives a voltage corresponding to a data voltage and the common electrode CE receives the low potential voltage, a potential difference is formed between the pixel electrodes AE1, AE2, and AE3 and the common electrode CE, so that the light emitting layer EL may emit light.

The pixel defining layer PDL may include a plurality of openings and may be located on a part of the pixel electrodes AE1, AE2, and AE3 and the second passivation layer PAS2. Each opening of the pixel defining layer PDL may expose a part of the pixel electrodes AE1, AE2, and AE3. As described above, the respective openings of the pixel defining layer PDL may define the first to third emission areas, and the areas or sizes thereof may be different from each other. The pixel defining layer PDL may separate and insulate the pixel electrodes AE1, AE2, and AE3 of each of the plurality of light emitting elements ED. The pixel defining layer PDL may include a light absorbing material to prevent or reduce light reflection. For example, the pixel defining layer PDL may include a polyimide (PI)-based binder and a pigment in which red, green, and blue colors are mixed. Alternatively, the pixel defining layer PDL may include a cardo-based binder resin and a mixture of a lactam black pigment and a blue pigment. Alternatively, the pixel defining layer PDL may include carbon black.

The encapsulation layer TFEL may be located on the common electrode CE to cover the plurality of light emitting elements ED. The encapsulation layer TFEL may include at least one inorganic layer to prevent or reduce instances of contaminants such as oxygen or moisture penetrating into the light emitting element layer EML. The encapsulation layer TFEL may include at least one organic layer to protect the light emitting element layer EML from foreign matters such as dust.

According to some embodiments, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 located between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, polyethylene and the like. For example, the second encapsulation layer TFE2 may include an acrylic resin, for example, polymethyl methacrylate, polyacrylic acid, or the like. The second encapsulation layer TFE2 may be formed by curing a monomer or applying a polymer.

The touch sensing layer TSU may be located on the encapsulation layer TFEL. The touch sensing layer TSU may include a first touch insulating layer SIL1, a second touch insulating layer SIL2, the touch electrode TL, and a third touch insulating layer SIL3.

The first touch insulating layer SIL1 may be located on the encapsulation layer TFEL. The first touch insulating layer SIL1 may have an insulating and optical function. The first touch insulating layer SIL1 may include at least one inorganic layer. Optionally, the first touch insulating layer SIL1 may be omitted.

The second touch insulating layer SIL2 may cover the first touch insulating layer SIL1. According to some embodiments, a touch electrode of another layer may be further located on the first touch insulating layer SIL1, and the second touch insulating layer SIL2 may cover the touch electrode TL. The second touch insulating layer SIL2 may have an insulating and optical function. For example, the second touch insulating layer SIL2 may be an inorganic layer containing at least one of a silicon nitride layer, a silicon oxynitride layer, a silicon oxide layer, a titanium oxide layer, or an aluminum oxide layer.

A part of the touch electrode TL may be located on the second touch insulating layer SIL2. The touch electrode TL may not overlap the first to third pixel electrodes AE1, AE2, and AE3. The touch electrode TL may be formed of a single layer containing molybdenum (Mo), titanium (Ti), copper (Cu), aluminum (AI), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The touch electrode TL of the touch sensing layer TSU may have a constant line width and may be arranged to overlap the light blocking layer BM, which will be described later. The light blocking layer BM may have a width sufficient to completely cover the touch electrode TL, and a gap between an edge of the light blocking layer BM and the touch electrode TL may be defined. According to some embodiments, the line width of the touch electrode TL may be in a range of 4 μm to 6 μm, and the gap between the touch electrode TL and the edge of the light blocking layer BM may be in a range of 5 μm to 7 μm. The touch electrode TL may be arranged such that the center thereof is almost parallel to the center of the light blocking layer BM, and the gap from both sides of the touch electrode TL to the edge of the light blocking layer BM may be approximately constant.

The third touch insulating layer SIL3 may cover the touch electrode TL and the second touch insulating layer SIL2. The third touch insulating layer SIL3 may have an insulating and optical function. The third touch insulating layer SIL3 may be made of the material described in association with the second touch insulating layer SIL2.

The light blocking layer BM may be located on the third touch insulating layer SIL3 of the touch sensing layer TSU. The light blocking layer BM may be arranged to cover the conductive line of the touch electrode TL, while including the plurality of holes OPT1, OPT2, and OPT3 that overlap the pixel electrodes AE1, AE2, and AE3. For example, the first hole OPT1 may be arranged to overlap the first pixel electrode AE1. The second hole OPT2 may be arranged to overlap the second pixel electrode AE2, and the third hole OPT3 may be arranged to overlap the third pixel electrode AE3. The areas or sizes of the holes OPT1, OPT2, and OPT3 may be larger than the areas or sizes of the pixel electrodes AE1, AE2, and AE3. In addition, the area or size of each of the holes OPT1, OPT2, and OPT3 may be formed to be larger than that of the corresponding opening of the pixel defining layer PDL, and light emitted from the light emitting element ED may be visually recognized by the user not only from the front of the display device 10 but also from the side thereof.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, or aniline black, but they are not limited thereto. The light blocking layer BM may prevent or reduce visible light infiltration and color mixture between the holes OPT1, OPT2, and OPT3, which leads to the improvement of color reproducibility of the display device 10. According to some embodiments, the light blocking layer BM may have a thickness of 1 μm to 3 μm, or approximately 1.5 μm.

The color filters CF1, CF2, and CF3 of the color filter layer CFL may be located on the light blocking layer BM. The different color filters CF1, CF2, and CF3 may be arranged to correspond to the different pixel electrodes AE1, AE2, and AE3 and the holes OPT1, OPT2, and OPT3 of the light blocking layer BM, respectively. For example, the first color filter CF1 may be arranged to correspond to the first pixel electrode AE1, the second color filter CF2 may be arranged to correspond to the second pixel electrode AE2, and the third color filter CF3 may be arranged to correspond to the third pixel electrode AE3. In the first pixel PX1, the first color filter CF1 may be located in the first hole OPT1 of the light blocking layer BM, the second color filter CF2 may be located in the second hole OPT2 of the light blocking layer BM, and the third color filter CF3 may be located in the third hole OPT3 of the light blocking layer BM. Each of the color filters CF1, CF2, and CF3 may be arranged to have a larger area in a plan view than the holes OPT1, OPT2, and OPT3 of the light blocking layer BM, and some may be located directly on the light blocking layer BM.

The areas of the plurality of color filters CF1, CF2, and CF3 may vary depending on the sizes of the holes OPT1, OPT2, and OPT3 of the light blocking layer BM. For example, the first color filter CF1 may have a larger area in a plan view than the second color filter CF2, but may have a smaller area in a plan view than the third color filter CF3.

The overcoat layer OC may be located on the light blocking layer BM and the color filter layer CFL. The overcoat layer OC may be arranged over the entire display area DA to flatten the top surface of the display device 10. The overcoat layer OC may be a colorless light transmissive layer that does not have a color in a visible light band. For example, the overcoat layer OC may include a colorless light transmissive organic material such as an acrylic resin.

According to some embodiments, the display device 10 may not include a polarizing plate on the overcoat layer OC. In other words, the polarizing plate may serve to prevent or reduce deterioration of display quality when external light is incident and reflected by the pixel electrode, the sidewall of the opening of the pixel defining layer PDL, or the like to be visible to the user. However, the polarizing plate has the disadvantage of consuming more power to display a certain luminance by not only reducing the reflection of external light but also reducing the light emitted from the light emitting element layer EML. In order to reduce power consumption, the light emitting display device according to some embodiments may not include a polarizing plate.

In addition, the display device 10 already includes a structure that prevents or reduces deterioration of display quality due to the reflection, the structure in which the side surface of the pixel electrode is covered with the pixel defining layer PDL to reduce the degree to which light is reflected from the pixel electrode and the light blocking layer BM is also formed to reduce the degree to which light is incident. Accordingly, there is no need to separately form the polarizing plate on the front surface of the display panel 100.

According to some embodiments, in the display device 10, the formation process of the overcoat layer OC may be performed using an inkjet printing process. Compared to the patterning process using photoresist, there is an advantage that one mask process may be eliminated and the manufacturing process of the display device 10 is shortened. For example, the overcoat layer OC may have a thickness in the range of 10 μm to 20 μm, a viscosity in the range of 10 cp to 20 cp, and a refractive index having a value of about 1.5. The overcoat layer OC may be formed through an inkjet printing process and may include a material that may improve the optical properties of the display device 10.

In addition, in the display device 10, layers located in the non-display area NDA or the sub-region SBA other than the display area DA may be replaced by layers made of the same material as the configuration of the other layers located in the display area DA, and the manufacturing process may be further shortened.

FIG. 8 is a plan view illustrating the arrangement of the color filter layer in a cell unit of the display device according to some embodiments. FIG. 9 is a cross-sectional view taken along the line X-X′ of FIG. 8. FIG. 9 illustrates a diagram crossing the bending area BA in the sub-region SBA of the display device 10 in the first direction DR1.

Referring to FIGS. 8 and 9, the display device 10 may be manufactured from a mother substrate in a cell unit CL, and may then be cut into the shape illustrated in FIG. 4 to be formed. The overcoat layer OC may be formed to overlap the display device 10 based on the mother substrate in the cell unit CL. The overcoat layer OC may be formed to fill an overcoat valley portion OCL surrounding a part of the display device 10 in the mother substrate in the cell unit CL. The overcoat valley portion OCL may surround a part of the main region MA and the sub-region SBA of the display device 10. The overcoat valley portion OCL may be formed to cross the upper side of the display driver 200 in the sub-region SBA of the display device 10.

A dam structure forming the overcoat valley portion OCL may be formed in the mother substrate in the cell unit CL. Among these, the overcoat valley portion OCL crossing the sub-region SBA of the display device 10 may be formed by a dam structure located in the sub-region SBA.

According to some embodiments, the display device 10 may include a plurality of color dams CFD1 and CFD2 forming a dam or valley that forms an area in which the overcoat layer OC is located, and a first color pattern CFP1 located on the same layer as the color dams CFD1 and CFD2 and covering a part of the bending area BA. The first color pattern CFP1 and the color dams CFD1 and CFD2 located in the sub-region SBA of the display device 10 may be located on the same layer as the color filter of the color filter layer CFL of the display area DA and may include the same material. Because the first color pattern CFP1 and the color dams CFD1 and CFD2 are formed simultaneously with the color filter in the same manner as the overcoat layer OC is formed through an inkjet printing process, the mask process during the manufacturing process may be reduced.

The bending area BA may include a bending structure PSV1, PSV2, SDL, and SPC including layers made of the same material as the layers located on the display layer DU of the display area DA. The bending structure PSV1, PSV2, SDL, and SPC may include a first via layer PSV1, a wiring layer SDL, a second via layer PSV2, and a spacer SPC. The first via layer PSV1 and the second via layer PSV2 may be located on the same layer as the first passivation layer PAS1 and the second passivation layer PAS2 of the thin film transistor layer TFTL, respectively, and the wiring layer SDL may be located on the same layer as the first connection electrode CNE1. The spacer SPC may be located on the second via layer PSV2. The wiring layer SDL of the bending structure PSV1, PSV2, SDL, SPC may be a layer that connects the wires located inside and outside the bending area BA, and the first passivation layer PAS1, the second passivation layer PAS2, and the spacer SPC may prevent or reduce instances of the wiring layer SDL being exposed to the outside. The wiring layer SDL may be connected to any one of the wires of a backplane layer TFL located inside and outside the bending area BA. The backplane layer TFL may have a structure in which a plurality of conductive layers and insulating layers are stacked, similarly to the thin film transistor layer TFTL.

The first color pattern CFP1 may be located adjacent to the main region MA, in the sub-region SBA. The first color pattern CFP1 may be arranged to cover a part of the bending area BA. The first color pattern CFP1 may cover a part of the bending structure PSV1, PSV2, SDL, and SPC and may form an opening area CFO that exposes a part of them. The first color pattern CFP1 may protect the wiring layer SDL and the bending structure PSV1, PSV2, and SPC located in the bending area BA, and may compensate for modulus characteristics when the bending area BA is folded. Additionally, the display device 10 may include a bending protection layer BPL located on the overcoat layer OC in the bending area BA, and the bending protection layer BPL may also compensate for the modulus characteristics and protect the wiring layer SDL, similarly to the first color pattern CFP1.

The plurality of color dams CFD1 and CFD2 may include a first color dam CFD1 located outside the bending area BA in the sub-region SBA, and a second color dam CFD2 spaced apart from the first color dam CFD1 and adjacent to the pads PD. The first color dam CFD1 may be spaced apart from the first color pattern CFP1 to form a first valley portion CFV1, and the second color dam CFD2 may be spaced apart from the first color dam CFD1 to form a second valley portion CFV2. The first and second valley portions CFV1 and CFV2 and the first and second color dams CFD1 and CFD2 may prevent or reduce instances of the overcoat layer OC formed in an inkjet printing process overflowing from the sub-region SBA to the pad PD. For example, the overcoat layer OC may not exceed at least the second color dam CFD2, may fill the first valley portion CFV1, and may overlap a part of the first color dam CFD1. The overcoat layer OC may cover the bending structure PSV1, PSV2, SDL, and SPC and the first color pattern CFP1.

According to some embodiments, the first color dam CFD1 and the second color dam CFD2 may have a width in the range of 30 μm to 60 μm, and the first and second valley portions CFV1 and CFV2 may also have a width in the range of 30 μm to 60 μm. Additionally, each of the first color dam CFD1 and the second color dam CFD2 may have a thickness in the range of 1 μm to 3 μm and a taper angle of the side surface in the range of 60° to 90°. The overcoat layer OC may be formed by the color dams CFD1 and CFD2 and the valley portions CFV1 and CFV2 so as not to exceed the overcoat valley portion OCL, and the pad PD of the sub-region SBA may not be covered by the overcoat layer OC.

Additionally, the second color dam CFD2 may not cover the portion, in which the display driver 200 is located, of the sub-region SBA. The second color dam CFD2 may include a first opening pattern COA1 formed to overlap the display driver 200.

The color dams CFD1 and CFD2 and the first color pattern CFP1 of the display device 10 may be located on the same layer as either the color filter layer CFL or the light blocking layer BM in the display area DA and may include the same material. A part of a touch insulating layer SIL of the touch sensing layer TSU may be located in the sub-region SBA, and the color dams CFD1 and CFD2 and the first color pattern CFP1 may be directly located on the touch insulating layer SIL. As an example, the color dams CFD1 and CFD2 and the first color pattern CFP1 may include the same material as the light blocking layer BM or any one of the first to third color filters CF1, CF2, and CF3 and may be simultaneously formed. According to some embodiments, the color dams CFD1 and CFD2 and the first color pattern CFP1 may include the same material as the second color filter CF2 and may be formed together with the second color filter CF2. The first color pattern CFP1 including the same material as the second color filter CF2 may be advantageous in compensating for the modulus characteristics when folded in the bending area BA.

Additionally, according to some embodiments, a second color pattern CFP2 arranged around the display device 10 may be formed on the mother substrate in the cell unit CL. The second color pattern CFP2 may be located on the outside of the display device 10 in the mother substrate in the cell unit CL. The second color pattern CFP2 may also form the overcoat valley portion OCL together with the color dams CFD1 and CFD2, and may prevent the overcoat layer OC from completely covering the sub-region SBA. Because the overcoat valley portion OCL is formed to surround the outside of the main region MA of the display device 10, when the overcoat layer OC is formed through an inkjet printing process, edge unevenness caused by humps formed when ink is partially clumped at the edge of the display device 10 may also be improved.

The mother substrate in the cell unit CL may be formed with a key for alignment with the process equipment. The key may be formed outside the display device 10, and the second color pattern CFP2 may include a plurality of second opening patterns COA2 that overlap the key so as not to cover the key. Accordingly, the key that helps recognize the alignment of process equipment and the mother substrate of the cell unit CL may be exposed while the overflow of the overcoat layer OC is prevented or reduced through the second color pattern CFP2.

The display device 10 according to some embodiments may reduce the mask process as the overcoat layer OC is performed through an inkjet printing process, and in addition, has an advantage that the manufacturing process may be further shortened because the color dams CFD1 and CFD2 that prevent or reduce the overflow of the overcoat layer OC in the sub-region SBA are formed at the same time as the color filter layer CFL or the light blocking layer BM.

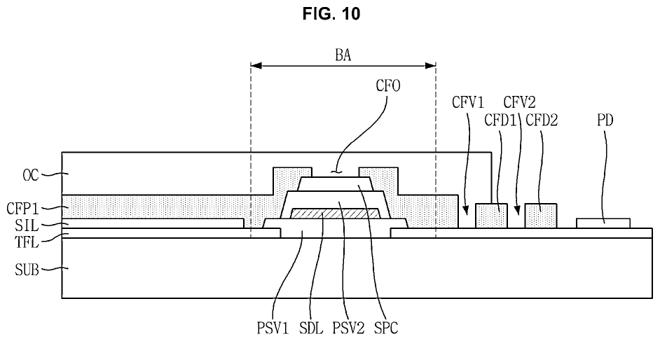

FIG. 10 is a cross-sectional view showing a bending area of a display device according to some embodiments.

Referring to FIG. 10, the display device 10 may omit the bending protection layer BPL. Because the display device 10 may compensate for the modulus characteristics of the bending area BA by covering a part of the bending area BA with the first color pattern CFP1, the bending protection layer BPL may be omitted. The present embodiments differ from the embodiments of FIG. 9 in that the bending protection layer BPL is omitted. As the bending protection layer BPL is omitted, the display device 10 may reduce a dead space by minimizing the bending area BA.

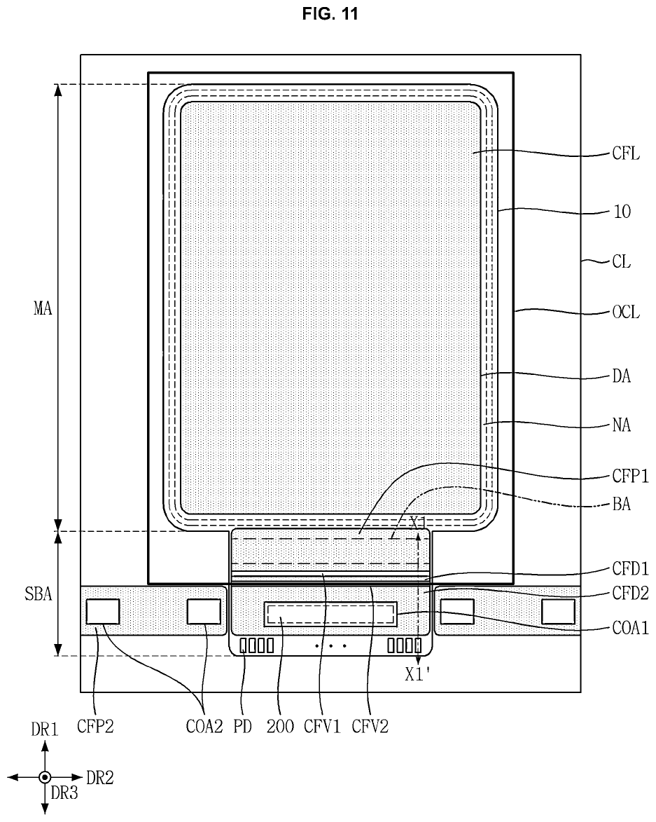

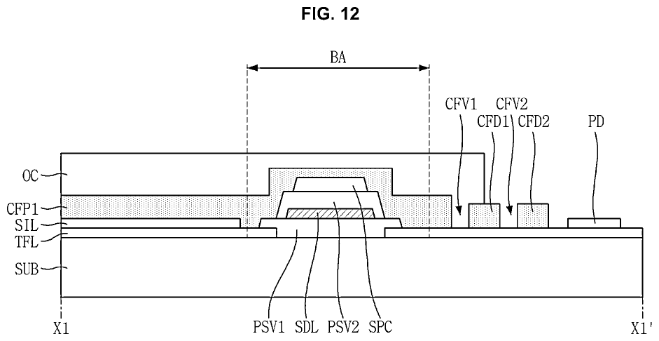

FIG. 11 is a plan view illustrating the arrangement of a color filter layer in a cell unit of a display device according to some embodiments. FIG. 12 is a cross-sectional view taken along the line X1-X1′ of FIG. 11.

Referring to FIGS. 11 and 12, in the display device 10 according to some embodiments, the first color pattern CFP1 may completely cover the bending area BA. The first color pattern CFP1 may completely cover the spacer SPC and the second via layer PSV2 of the bending structure PSV1, PSV2, SDL, and SPC without forming the opening area CFO. The first color pattern CFP1 may have excellent modulus characteristics depending on the material, and damage or lifting phenomena may not occur when the bending area BA is folded. In this case, the first color pattern CFP1 may completely cover the bending structure PSV1, PSV2, SDL, and SPC without forming the opening area CFO. Accordingly, the display device 10 may further strengthen the modulus characteristics of the bending area BA.

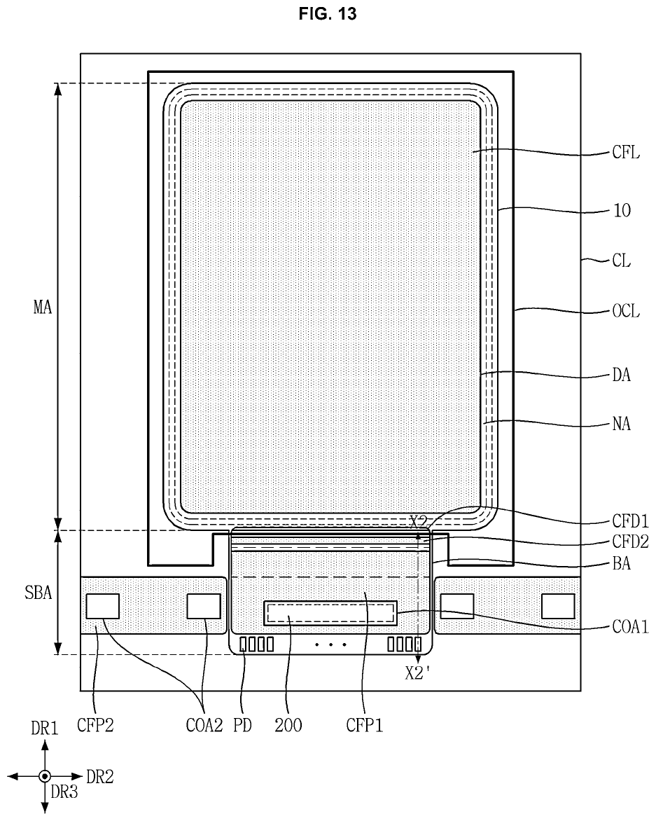

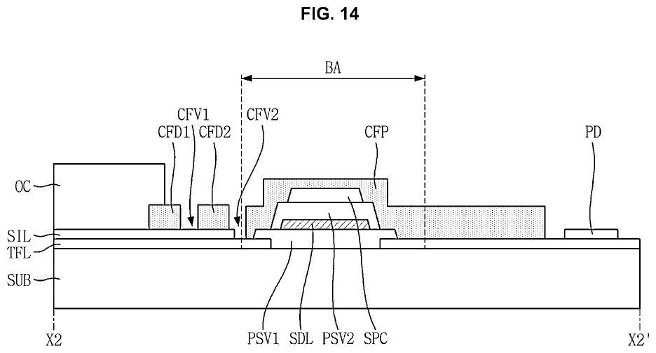

FIG. 13 is a plan view illustrating the arrangement of a color filter layer in a cell unit of a display device according to some embodiments. FIG. 14 is a cross-sectional view taken along the line X2-X2′ of FIG. 13.

Referring to FIGS. 13 and 14, in the display device 10 according to some embodiments, the plurality of color dams CFD1 and CFD2 may be located closer to the main region MA than the first color pattern CFP1. The first color pattern CFP1 may cover the bending structure PSV1, PSV2, SDL, and SPC and may be located in and outside the bending area BA in the sub-region SBA. The first color dam CFD1 and the second color dam CFD2 may be spaced apart from each other and may be located inside the bending area BA. The first color dam CFD1 and the second color dam CFD2, and the first color pattern CFP1 may be spaced apart from each other to form a plurality of valley portions CFV1 and CFV2, and the overcoat layer OC may not exceed at least the second color dam CFD2. The overcoat layer OC may fill the first valley portion CFV1 and partially overlap the first color dam CFD1. The overcoat layer OC may not overlap the first color pattern CFP1.

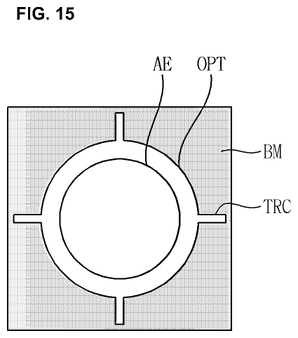

FIG. 15 is a plan view illustrating an opening in a light blocking layer of a display device according to some embodiments. FIG. 15 illustrates the relative planar arrangement of one pixel electrode AE of the display area DA and a hole OPT of the light blocking layer BM.

Referring to FIG. 15, in the display device 10, the light blocking layer BM located in the display area DA may further include a trench TRC that protrudes from the outer side of the hole OPT. The hole OPT of the light blocking layer BM may have a generally circular shape, but the trench TRC may be formed with the outer side protruding in a plan view. The trench TRC may be formed to penetrate the light blocking layer BM in the same way as the hole OPT. In FIG. 15, the four trenches TRC are formed in the one hole OPT at regular intervals, but embodiments according to the present disclosure are not limited thereto. According to some embodiments, the width of the trench TRC may be a size of 1 to 2 micrometers (μm).

As the overcoat layer OC is formed through an inkjet printing process, an area that cannot be partially filled may be formed due to a stepped portion formed by the light blocking layer BM and the color filter layer CFL located therebelow. In the light blocking layer BM, as the trench TRC formed on the outer side of the holes OPT is formed to penetrate the light blocking layer BM, the color filters CF1, CF2, and CF3 may be formed to fill the trench TRC in addition to the hole OPT. Accordingly, the stepped portion caused by the color filters CF1, CF2, and CF3 may be reduced, and it may be advantageous for the overcoat layer OC located on the color filters CF1, CF2, and CF3 to be formed to completely fill the gap between the color filter layer CFL and the light blocking layer BM.

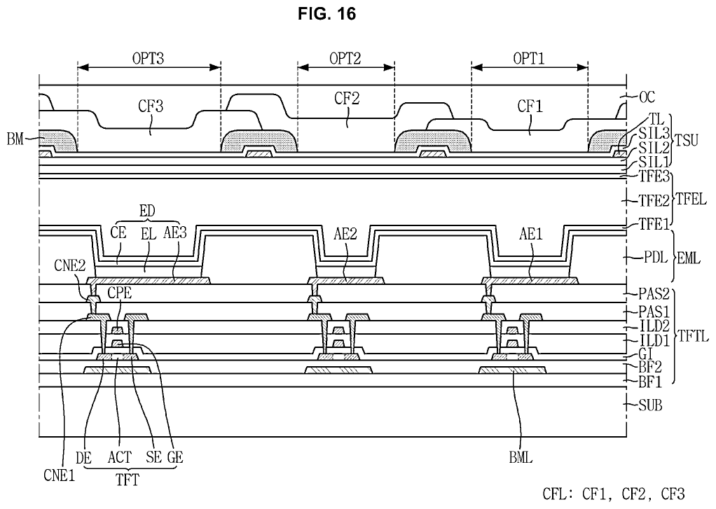

FIGS. 16 to 18 are cross-sectional views of a display device according to some embodiments.

Referring to FIG. 16, in the display device 10 according to some embodiments, the color filters CF1, CF2, and CF3 may be arranged to partially overlap each other. The plurality of color filters CF1, CF2, and CF3 may overlap different color filters adjacent to each other on the light blocking layer BM. For example, the second color filter CF2 may overlap each of the first color filter CF1 and the third color filter CF3 adjacent on the light blocking layer BM. According to some embodiments, the first color filter CF1 may overlap the third color filter CF3 on the light blocking layer BM, and in some embodiments, the first color filter CF1, the second color filter CF2, and the third color filter CF3 may all overlap.

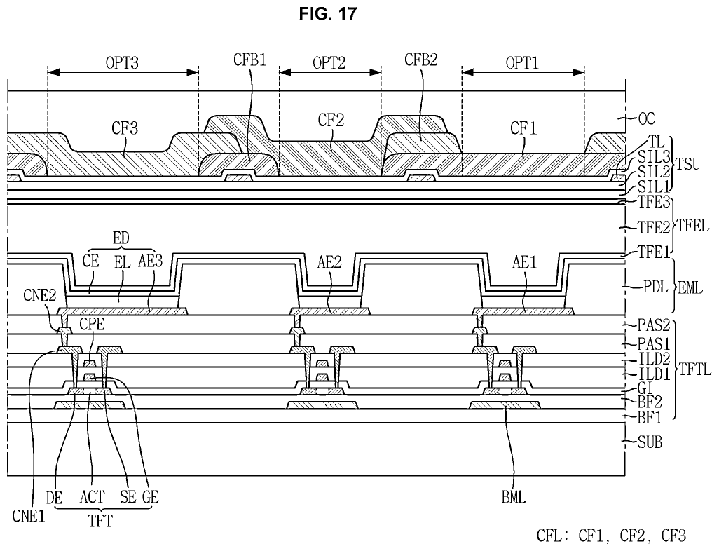

Referring to FIG. 17, the display device 10 according to some embodiments may omit the light blocking layer BM and may include color light blocking layers CFB1 and CFB2 including the same material as the color filters CF1, CF2, and CF3. The color filters CF1, CF2, and CF3 and the color light blocking layers CFB1 and CFB2 may overlap each other between the adjacent emission areas EA and may play the same role as the light blocking layer BM.

For example, the first color filter CF1 may overlap the first pixel electrode AE1 and may be arranged to cover the peripheral area. The first color light blocking layer CFB1 including the same material as the first color filter CF1 may be located at the boundary between the emission area overlapping the second pixel electrode AE2 and the emission area overlapping the third pixel electrode AE3.

The third color filter CF3 may overlap the third pixel electrode AE3 and may be arranged to cover the peripheral area. A part of the third color filter CF3 may be located on the first color filter CF1 and the first color light blocking layer CFB1. The first color filter CF1 may be located at the boundary between the emission area overlapping the first pixel electrode AE1 and the emission area overlapping the second pixel electrode AE2, and the second color light blocking layer CFB2 including the same material as the third color filter CF3 may be located thereon.

The second color filter CF2 may overlap the second pixel electrode AE2 and may be arranged to cover the peripheral area. A part of the second color filter CF2 may be located on the first color light blocking layer CFB1 and the second color light blocking layer CFB2.

The color filters CF1, CF2, and CF3 or the color light blocking layers CFB1 and CFB2 including different colorants may overlap at the boundary between the emission areas overlapping the respective pixel electrodes AE1, AE2, and AE3. Accordingly, it may perform the same role as the light blocking layer BM and block the transmission of light. The hole areas OPT1, OPT2, and OPT3 may be formed in the area of the color filters CF1, CF2, and CF3, which does not overlap the color light blocking layers CFB1 and CFB2 or the color filters CF1, CF2, and CF3 of different colorants.

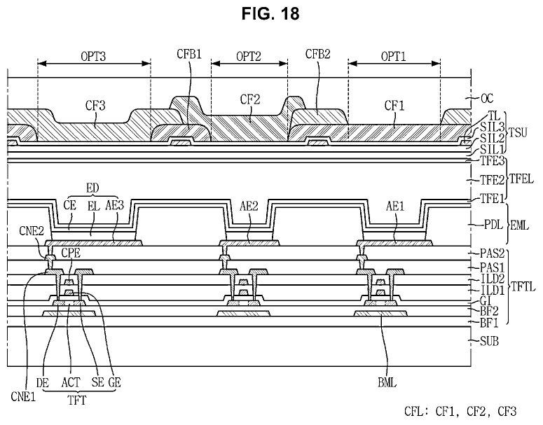

Referring to FIG. 18, in the display device 10, the color light blocking layers CFB1 and CFB2 and the color filters CF1, CF2, and CF3 may partially overlap. For example, the second color filter CF2 may not completely overlap but may partially overlap the first color filter CF1, the first color light blocking layer CFB1, and the second color light blocking layer CFB2. The third color filter CF3 may overlap the first color filter CF1 and the first color light blocking layer CFB1. In the embodiments of FIG. 17, the color filters CF1, CF2, and CF3 or the color light blocking layers CFB1 and CFB2 of three different colors may overlap each other at the boundaries of the adjacent holes OPT1, OPT2, and OPT3, but in the embodiments of FIG. 18, the color filters CF1, CF2, and CF3 or the color light blocking layers CFB1 and CFB2 of two different colors may overlap each other at the boundaries of the adjacent holes OPT1, OPT2, and OPT3.

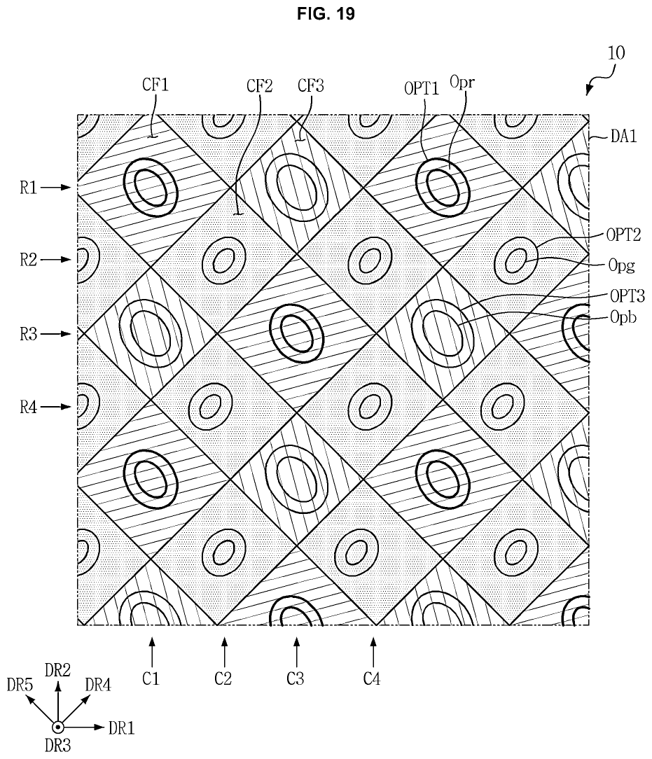

FIG. 19 is a plan view illustrating the arrangement of an opening of a pixel defining layer and color filters in a display area of a display device according to some embodiments.

Referring to FIG. 19, in the display device 10 according to some embodiments, openings Opr, Opg, and Opb of the pixel defining layer and the corresponding holes OPT1, OPT2, and OPT3 of the light blocking layer BM may have an elliptical shape. The long axes of the elliptical openings Opr, Opg, and Opb of the pixel defining layer and the holes OPT1, OPT2, and OPT3 of the light blocking layer BM may have different directions from each other. According to some embodiments, the pixel electrodes AE1, AE2, and AE3 may also have an elliptical shape similarly to the openings Opr, Opg, and Opb of the pixel defining layer.

In the display device 10, the openings Opr, Opg, and Opb of the plurality of pixel defining layers and the holes OPT1, OPT2, and OPT3 of the light blocking layer BM may each have an elliptical planar shape with the same eccentricity. That is, the first opening Opr, the second opening Opg, and the third opening Opb may be all ellipses with the same eccentricity, and the first hole OPT1, the second hole OPT2, and the third hole OPT3 may also be all ellipses with the same eccentricity. Here, the eccentricity of the openings Opr, Opg, and Opb and the holes OPT1, OPT2, and OPT3 may have a value greater than or equal to 0 and less than or equal to 0.85.

Here, the ellipse may have two foci, may have a shape connecting points in which the sum of the distances to the two foci is constant, and may have a long axis and a short axis. Meanwhile, the eccentricity of the ellipse is a value obtained by dividing the distance between the two foci by the length of the long axis. When the eccentricity is 0, it is a circle, and when it is 1, it forms a parabola, so that the ellipse has a value that is greater than 0 and less than 1 as an eccentricity value.

The one opening Opr, Opg, Opb may overlap the one hole OPT1, OPT2, OPT3 and may have a certain horizontal gap from each other. Here, the horizontal gap or separation distance between the openings Opr, Opg, and Opb and the corresponding holes OPT1, OPT2, and OPT3 may be greater than 0 μm and less than or equal to 20 μm, and the horizontal gap may change depending on the thickness of a layer (e.g., an encapsulation layer) positioned between the two in cross-sectional view. In addition, according to some embodiments, the directions of the long axes of the openings Opr, Opg, and Opb and the holes OPT1, OPT2, and OPT3 may form a certain angle due to process errors, or the like, and may have an angle greater than or equal to 0 degrees and less than or equal to 20 degrees.

In the embodiments of FIG. 19, the angle formed by each long axis of the plurality of openings Opr, Opg, and Opb or holes OPT1, OPT2, and OPT3 may have angles that are four or more angles, and the angles formed by the long axes may be located at intervals of an angle of 45 degrees or less.

As an example, focusing on embodiments with five angles, a specific angle relationship will be described below. In the embodiments with five angles, the angles of the long axes are formed at intervals of 36 degrees, so that when one long axis has 0 degrees with respect to the first direction DR1, there are the angles of 36 degrees, 72 degrees, 108 degrees, and 144 degrees, which results in a total of five angles. In other words, regarding the five angles, the intervals between the angles of the long axes may be checked by dividing the angle of 180 degrees by 5, which is the number of directions, and this is because the two angles with the angle of 180 degrees out of the angle of 360 degrees have substantially the same long axis direction of the ellipse and this may mean calculating by dividing 180 degrees by the number of directions.

As described above, the angles of the long axes of the openings Opr, Opg, and Opb and the holes OPT1, OPT2, and OPT3 may be located at equal intervals at a specific angle of 45 degrees or less. However, according to some embodiments, the angle formed by the long axis of each opening may be one of the angles of 45 degrees or less and may be arranged at irregular intervals. In the embodiments in which the long axes of the openings are arranged at non-equal intervals, the long axes may be intentionally arranged to reduce the diffraction pattern, or may be arranged at non-equal intervals due to processing errors.

In order for the unit pixel including the openings Opr, Opg, and Opb and the holes OPT1, OPT2, and OPT3 of red, green, and blue colors to have a square structure, it may be appropriate that the angle of the long axis is formed by the division with a number corresponding to the square of an integer, for example, 22, 32, 42, 52, or the like. Here, the unit pixel may include each one from the openings Opr, Opg, and Opb and the holes OPT1, OPT2, and OPT3 of red, green, and blue colors, and the hole OPT1, OPT2, OPT3 of one color among them, for example, the hole OPT2 of a green color may be formed in plurality.

In concluding the detailed description, those skilled in the art will appreciate that many variations and modifications can be made to the disclosed embodiments without substantially departing from the spirit and scope of embodiments according to the present disclosure. Therefore, the disclosed embodiments of the invention are used in a generic and descriptive sense only and not for purposes of limitation.

What is claimed is:

1. A display device comprising:
a substrate having a main region where a plurality of pixel electrodes spaced apart from each other are located, and a sub-region on one side of the main region and comprising a bending area;
a plurality of color filters overlapping the pixel electrode on the substrate;
a first color pattern on the substrate and partially overlapping the bending area in the sub-region;
a first color dam spaced apart from the first color pattern and in the sub-region, and a second color dam spaced apart from the first color dam; and
an overcoat layer on a color filter from among the color filters and in the main region and the sub-region,
wherein the overcoat layer covers the main region and is on an inside of the second color dam in the sub-region.

2. The display device of claim 1, wherein each of the first color pattern, the first color dam, and the second color dam includes a same material as the color filter.

3. The display device of claim 1, wherein
a part of the first color pattern is between the main region and the bending area of the sub-region, and
the first color dam is spaced apart from the first color pattern outside the bending area.

4. The display device of claim 3, wherein the overcoat layer overlaps the first color pattern in the sub-region.

5. The display device of claim 3, further comprising a bending protection layer on the overcoat layer and overlapping the bending area.

6. The display device of claim 3, further comprising a bending structure comprising a plurality of via layers in the bending area and a wiring layer between the via layers,
wherein at least a part of the first color pattern covers the bending structure.

7. The display device of claim 6, wherein the first color pattern completely covers the bending structure.

8. The display device of claim 3, wherein the overcoat layer fills a first valley portion formed between the first color dam and the first color pattern and is on an inside of the first color dam.

9. The display device of claim 1, wherein
a part of the first color pattern is outside the bending area of the sub-region,
the first color dam is between the bending area and the main region, and
the second color dam is between the first color dam and the bending area.

10. The display device of claim 9, wherein the overcoat layer does not overlap the first color pattern.

11. The display device of claim 9, wherein the overcoat layer is on an inside of the first color dam.

12. The display device of claim 1, wherein
each of the first color dam and the second color dam has a width in a range of 30 micrometers (μm) to 60 μm, and
a valley portion formed between the first color dam and the second color dam has a width in a range of 30 μm to 60 μm.

13. The display device of claim 1, wherein the display device does not comprise a polarizing plate.

14. The display device of claim 1, further comprising a light blocking layer in the main region and comprising a plurality of holes overlapping the plurality of pixel electrodes,
wherein the plurality of color filters are respectively overlapping the holes of the light blocking layer.

15. The display device of claim 14, wherein the plurality of color filters overlap each other on the light blocking layer.

16. The display device of claim 1, wherein among the plurality of color filters, different color filters adjacent to each other overlap each other,
the display device further comprising a plurality of color light blocking layers in a region where the different color filters overlap.

17. A display device comprising:
a main region in which a plurality of pixel electrodes arranged in a first direction and a second direction are located, and a sub-region on one side of the main region in the first direction and in which a bending area is formed;
a light blocking layer comprising a plurality of holes overlapping the plurality of pixel electrodes in the main region;
a plurality of color filters on the light blocking layer and respectively corresponding to the plurality of holes;
a first color pattern in the sub-region, and at least partially overlapping the bending area;
a first color dam in the sub-region and spaced apart from the first color pattern, and a second color dam spaced apart from the first color dam; and
an overcoat layer covering a part of the sub-region and the main region, wherein
each of the first color pattern, the first color dam, and the second color dam is on a same layer as one of the color filters, and
the overcoat layer is on an inside of at least one of the first color dam or the second color dam in the sub-region.

18. The display device of claim 17, wherein
a part of the first color pattern is between the main region and the bending area of the sub-region, and
the first color dam is outside the bending area.

19. The display device of claim 17, wherein
a part of the first color pattern is outside the bending area of the sub-region,
the first color dam is between the bending area and the main region, and
the second color dam is between the first color dam and the bending area.

20. The display device of claim 17, wherein the light blocking layer comprises at least one trench formed on an outer side of a hole from among the holes and penetrating the light blocking layer.
